(19) United States
(12) Patent Application Publication
(10) Pub. No.: US 2017/0373111 A1
(43) Pub. Date: Dec. 28, 2017

(54) PHOTOSENSOR SUBSTRATE AND METHOD OF PRODUCING THE SAME

(71) Applicant: Sharp Kabushiki Kaisha, Sakai City, Osaka (JP)

(72) Inventors: ATSUSHI TOMYO, Sakai City (JP); TADAYOSHI MIYAMOTO, Sakai City (JP); KAZUHIDE TOMIYASU, Sakai City (JP); KAZUATSU ITO, Sakai City (JP)

(21) Appl. No.: 15/539,661

(22) PCT Filed: Dec. 17, 2015
(86) PCT No.: PCT/JP2015/085411

§ 371 Date: Jun. 23, 2017

(30) Foreign Application Priority Data
Dec. 25, 2014 (JP) 2014-262402

(51) Int. Cl. H01L 27/146; G01T 1/24; H01L 21/768; G01T 1/20

(52) U.S. Cl. CPC H01L 27/14636; H01L 27/14683; H01L 27/14658; G01T 1/2018; G01T 1/241; H01L 21/76879

(57) ABSTRACT

A photosensor substrate (10) includes a plurality of sensor units (1). The sensor units (1) each include a switching element (2), a lower electrode (3) connected to the switching element (2), and a photoelectric conversion element (4). The photosensor substrate (10) includes lines (G and D) connected to the switching elements of the plurality of sensor units and led out of a sensor area (SA), and terminal parts (TG and TD) connected to the lines (G and D) led out of the sensor area (SA). The terminal parts (TG and TD) each include a protective layer (4a) overlapped with the line (G or D) led out of the sensor area and containing a material for the photoelectric conversion element (4), and a terminal conductor (6) connected to the line (G or D) via an opening (CH1) provided in the protective layer (4a).

### TECHNICAL FIELD

The present invention relates to a photosensor substrate including a photoelectric conversion element, and a method of producing the same.

### BACKGROUND ART

A photosensor for a flat panel can be formed by arraying, on a substrate, switching elements and photoelectric conversion elements in a matrix form. For example, a photosensor array substrate disclosed in JP 5262212 B1 includes photodiodes and thin film transistors (TFTs) arrayed in a matrix form to configure an active matrix TFT array. Such a photosensor array substrate is applicable to a contact image sensor, an X-ray imaging display device, and the like.

### CITATION LIST

### Patent Literature

### Patent Literature 1: JP 5262212 B1

### SUMMARY OF INVENTION

### Technical Problems

A photosensor array substrate includes lines that are connected to switching elements such as TFTs and led out of a sensor area. The lines led out of the sensor area each have a terminal part exposed in a production step. The exposed terminal part of the line may have deterioration in surface condition by an etching residue, overetching, or the like. Such surface deterioration at the terminal part of the line may cause defective conduction and the like. Examples of measures to the defect include temporarily covering the terminal part with a protective film in a production process. Such a measure leads to increase in the number of production steps as well as increase in production cost.

In view of the above, the present application discloses a photosensor substrate and a method of producing the same, which inhibits increase in the number of production steps and surface deterioration at a terminal part of a line.

### Solution to Problems

A photosensor substrate according to an embodiment of the present invention includes a plurality of sensor units. The sensor units each includes a switching element, a lower electrode connected to the switching element, and a photoelectric conversion element disposed in contact with the lower electrode. The photosensor substrate further includes: a line connected to the switching element in corresponding one of the sensor units and led out of a sensor area provided with the plurality of sensor units; and a terminal part connected, outside the sensor area, to the line led out of the sensor area. The terminal part includes a protective layer overlapped with the line led out of the sensor area and containing a material for the photoelectric conversion element, and a terminal conductor connected to the line via at least one opening provided in the protective layer.

### Effects of Invention

The present disclosure achieves inhibition of increase in the number of production steps as well as inhibition of surface deterioration at a terminal part of a line.

### BRIEF DESCRIPTION OF DRAWINGS

FIG. 1 is a plan view depicting an exemplary configuration of a photosensor substrate according to the present embodiment.

FIG. 2 is a view depicting an exemplary configuration of an X-ray image detection device including the photosensor substrate of FIG. 1.

FIG. 3 is a view in a direction perpendicular to the substrate, depicting exemplary configurations of a sensor unit and a terminal part.

FIG. 4 is a sectional view taken along line IV-IV indicated in FIG. 3.

FIG. 5 is a sectional view taken along line V-V indicated in FIG. 3.

FIG. 6 is a view of terminal parts T according to a modification example.

FIG. 7 is a view of a terminal part T according to another modification example.

FIG. 8 is a view of a terminal part T according to still another modification example.

FIG. 9 is a view of a terminal part T according to still another modification example.

FIG. 10A is a view depicting an exemplary step of producing the photosensor substrate.

FIG. 10B is a view depicting an exemplary step of producing the photosensor substrate.

FIG. 10C is a view depicting an exemplary step of producing the photosensor substrate.

FIG. 10D is a view depicting an exemplary step of producing the photosensor substrate.

FIG. 10E is a view depicting an exemplary step of producing the photosensor substrate.

FIG. 10F is a view depicting an exemplary step of producing the photosensor substrate.

FIG. 10G is a view depicting an exemplary step of producing the photosensor substrate.

### DESCRIPTION OF EMBODIMENTS

A photosensor substrate according to an embodiment of the present invention includes a plurality of sensor units. The sensor units each includes a switching element, a lower electrode connected to the switching element, and a photoelectric conversion element disposed in contact with the lower electrode. The photosensor substrate further includes: a line connected to the switching element in corresponding one of the sensor units and led out of a sensor area provided with the plurality of sensor units; and a terminal part connected, outside the sensor area, to the line led out of the sensor area. The terminal part includes a protective layer overlapped with the line led out of the sensor area and containing a material for the photoelectric conversion element, and a terminal conductor connected to the line via at least one opening provided in the protective layer.

In this configuration, the line is covered with the protective layer at the terminal part connected to the line led out of the sensor area. This configuration is less likely to cause surface deterioration of the line at the terminal part. Furthermore, the protective layer contains the material for the photoelectric conversion element and thus needs no additional protective film. This inhibits increase in the number of the production steps for formation of such an additional protective layer. For example, the protective layer can be formed by patterning the photoelectric conversion element to leave the film of the photoelectric conversion element at the terminal part in the step of forming the photoelectric conversion element.

The photoelectric conversion element can be disposed above a layer having the line and at least in an area overlapped with the lower electrode. Furthermore, the protective layer containing the material for the photoelectric conversion element can be disposed outside the sensor area, above the layer having the line, and at least in an area overlapped with the terminal part. The photoelectric conversion element and the protective layer can be formed efficiently by providing the photoelectric conversion element and the protective layer above the layer having the line.

The line can have an end provided at the terminal part and overlapped with the protective layer in a direction perpendicular to the photosensor substrate. The end of the line is also protected by the protective film. This configuration inhibits surface deterioration of the line more effectively.

The at least one opening of the protective layer at the terminal part of at least one of the lines optionally includes a plurality of openings. This configuration is less likely to cause defective conduction at the terminal part.

The lines can include a plurality of gate lines extending in a first direction, and a data line provided on an insulating film to be different in layer level from the gate lines and extending in a second direction different from the first direction. The switching element can include a gate electrode connected to corresponding one of the gate lines, a semiconductor layer positioned to face the gate electrode via the insulating film interposed therebetween, a source electrode disposed on the semiconductor layer and connected to the data line, and a drain electrode positioned to face the source electrode on the semiconductor layer and connected to the lower electrode. The photoelectric conversion element can be disposed on the lower electrode and is positioned to be overlapped with the lower electrode. The terminal part can include, outside the sensor area, the protective layer overlapped above the gate line or the data line, and the terminal conductor connected to the gate line or the data line via the opening of the protective layer.

This configuration achieves the sensor area including the photoelectric conversion element provided on the data line, the semiconductor layer of the switching element, and the layer provided with the source electrode and the drain electrode. The terminal part outside the sensor area can be provided, on the layer of the gate line or the data line, with the protective layer containing the material for the photoelectric conversion element. The terminal part can thus be easily provided with the protective layer containing the material for the photoelectric conversion element and covering the gate line or the data line led out of the sensor area.

The photosensor substrate can further include: an upper electrode disposed on the photoelectric conversion element; and an upper electrode layer disposed on the protective layer at the terminal part. The protective layer and the electrode layer provided thereon can be structured similarly to the layer structure of the photoelectric conversion element and the upper electrode. The upper electrode on the photoelectric conversion element and the upper electrode layer on the protective layer can be made of an identical material.

The photoelectric conversion element and the protective layer according to an aspect can each include a p-type semiconductor layer, an n-type semiconductor layer, and an i-type semiconductor layer disposed between the p-type semiconductor layer and the n-type semiconductor layer. The photoelectric conversion element and the protective layer can thus be structured simply.

An X-ray image detection device according to an exemplary embodiment of the present invention includes: the photosensor substrate described above; and a scintillator layer positioned to be overlapped with the photoelectric conversion element of the photosensor substrate. This configuration achieves the X-ray image detection device less likely to cause a defect at the terminal part.

There is provided a method of producing a photosensor substrate according to an embodiment of the present invention. The method includes: forming, on a substrate, a line, a switching element connected to the line, and a lower electrode connected to the switching element; forming a photoelectric conversion element layer covering at least the lower electrode and a portion to be provided with a terminal part of the line; patterning the photoelectric conversion element layer to leave the photoelectric conversion element layer positioned to be overlapped with the lower electrode and the terminal part; forming a through hole penetrating the photoelectric conversion element layer overlapped with the terminal part of the line; and filling the through hole with a conductor.

This production method includes patterning the photoelectric conversion element layer to leave the photoelectric conversion element layer positioned to be overlapped with the lower electrode and the terminal part. This configuration protects the line at the terminal part. This is thus less likely to cause deterioration of the electrode at the surface of the terminal part. Furthermore, this production method needs to include no additional step for provision of the protective layer. This production method thus achieves inhibition of increase in the number of production steps as well as inhibition of surface deterioration at the terminal part of the line.

Embodiments of the present invention will be described in detail below with reference to the drawings. Identical or corresponding portions in the drawings will be denoted by identical reference signs and will not be described repeatedly. For dearer description, the drawings to be referred to hereinafter may depict simplified or schematic configurations or may not depict some of constructional elements. The constructional elements in each of the drawings may not necessarily be depicted at actual dimensional ratios.

### Embodiment 1

(Exemplary Configuration of Photosensor Substrate)

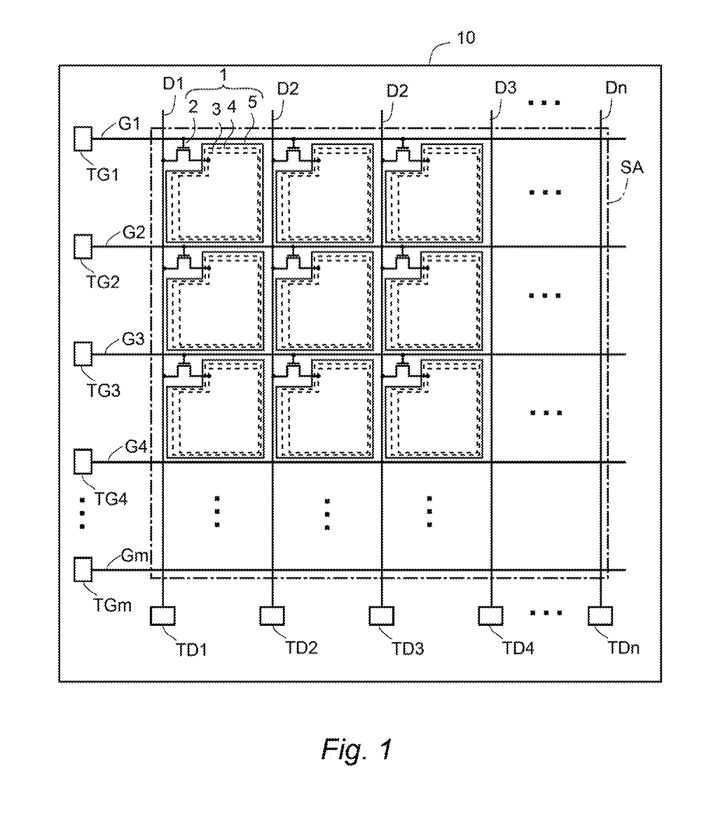

FIG. 1 is a plan view depicting an exemplary configuration of a photosensor substrate according to the present embodiment. FIG. 1 depicts a photosensor substrate 10 provided with a plurality of gate lines G1, G2, . . . and Gm (hereinafter, collectively called gate lines G when not distinguished from one another) extending in a lateral direction (exemplifying a first direction) and a plurality of data lines D1, D2, . . . and Dn (hereinafter, collectively called data lines D when not distinguished from one another) extending in a longitudinal direction (exemplifying a second direction) crossing the gate lines G. There are provided thin film transistors 2 (hereinafter, called TFTs) exemplifying switching elements and positioned correspondingly to intersection points of the gate lines G and the data lines D. The TFTs 2 are each connected to the gate line G, the data line D, and a lower electrode 3. The lower electrode 3 connected to each of the TFTs 2 is disposed in an area surrounded with the two adjacent gate lines G and the two adjacent data lines D. Each of the lower electrodes 3 is overlapped with a photodiode 4 exemplifying a photoelectric conversion element and an upper electrode 5. The lower electrode 3, the photodiode 4, and the upper electrode 5 are overlapped in the mentioned order in a direction perpendicular to a plane of the photosensor substrate 10.

One set of the TFT 2, the lower electrode 3, the photodiode 4, and the upper electrode 5 configures a single sensor unit 1. The sensor units 1 are arrayed in a matrix form along the plane of the photosensor substrate 10. The sensor units 1 are each disposed in the area surrounded with the two adjacent gate lines G and the two adjacent data lines D. The lower electrode 3 in each of the sensor units 1 stores electric charges in accordance with an amount of light received by the photodiode 4. The TFTs 2 each receive signals for control to turn ON and OFF the TFT via the gate line G. When the TFT 2 comes into an ON state, the electric charges stored in the lower electrode 3 is outputted to the data line D. There is thus acquired data indicating an amount of received light (detection amount) at each of the sensor units 1. This achieves acquisition of an image having pixels respectively corresponding to the sensor units 1.

The photosensor substrate 10 has an area provided with the sensor units 1 when viewed in a direction perpendicular to the substrate, in other words, a light detection area to be called a sensor area SA. The gate lines G and the data lines D are connected to the sensor units 1 within the sensor area SA. The gate lines G and the data lines D are led out of the sensor area. Outside the sensor area, the gate lines G1 to Gm are connected to terminal parts TG1 to TGm, respectively, (hereinafter, collectively called terminal parts TG when not distinguished from one another), whereas the data lines D1 to Dn are connected to terminal parts TD1 to TDn, respectively (hereinafter, collectively called terminal parts TD when not distinguished from one another). According to this example, the gate lines G each have an end connected to corresponding one of the terminal parts TG, and the data lines D each have an end connected to corresponding one of the terminal parts TD. The terminal parts TG and the terminal parts TD will hereinafter be collectively called terminal parts T when not particularly distinguished from each other.

The terminal part TG of each of the gate lines G can be connected with a circuit configured to output a drive signal supplied to the gate line G. The terminal part TD of each of the data lines D can be connected with a circuit (e.g. an amplifier configured to amplify a signal or an A/D converter configured to perform A/D conversion of a signal (conversion between an analog signal and a digital signal)) configured to process a signal outputted from the data line D.

(Exemplary Application to X-Ray Image Detection Device)

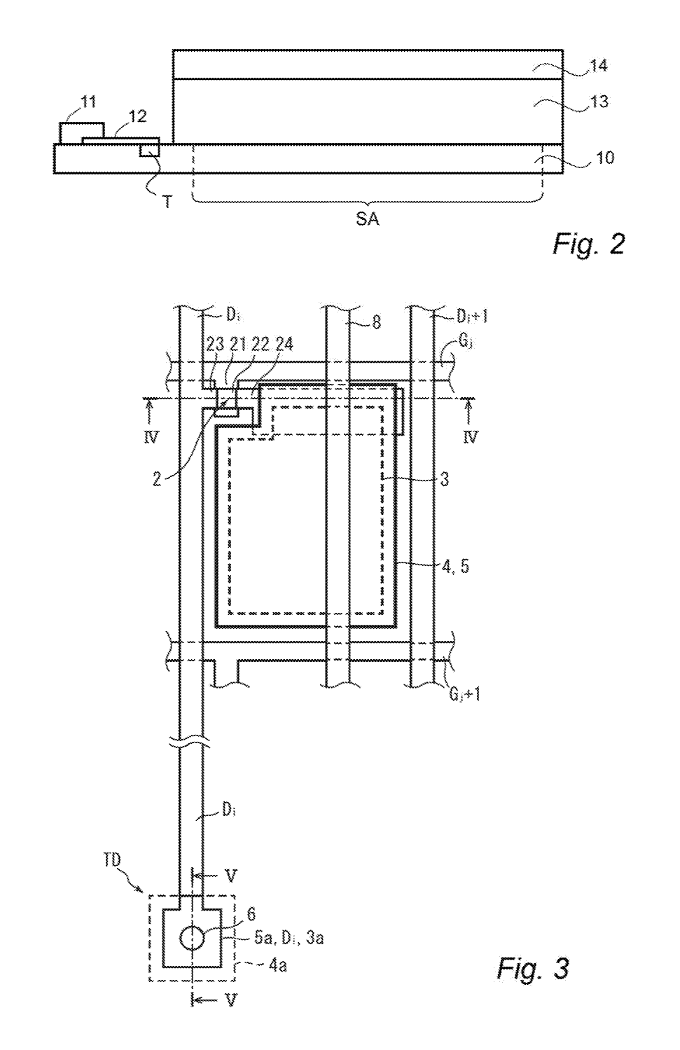

FIG. 2 is a view depicting an exemplary configuration of an X-ray image detection device including the photosensor substrate 10 of FIG. 1. FIG. 2 depicts a layer configuration in a plane perpendicular to the plane of the photosensor substrate 10. The photosensor substrate 10 is provided with a scintillator layer 13 positioned to be overlapped with the sensor area. The scintillator layer 13 can be made of a fluorescent material that converts X-rays to visible rays. Examples of the fluorescent material include cesium iodide (Csl). The scintillator layer 13 can be obtained by direct film formation, such as attachment or vapor deposition, to a surface of the photosensor substrate 10. The scintillator layer 13 can be provided thereon with a protective layer 14 covering the scintillator layer 13. This configuration achieves a flat panel detector (FDP) for an X-ray image.

The terminal parts T at the photosensor substrate 10 are each connected with an electronic component 11 via a line 12. The electronic component 11 can be configured by a semiconductor chip including a circuit configured to process a signal transmitted to the sensor unit 1 or a signal outputted from the sensor unit 1. The circuit connected to the terminal part T is not necessarily mounted to the semiconductor chip. The circuit can be mounted on the photosensor substrate 10 in accordance with the chip on glass (COG) method or the like, or can be provided at each of flexible printed circuits (FPCs) connected to the terminal parts T.

(Detailed Exemplary Configurations of Sensor Unit and Terminal Part)

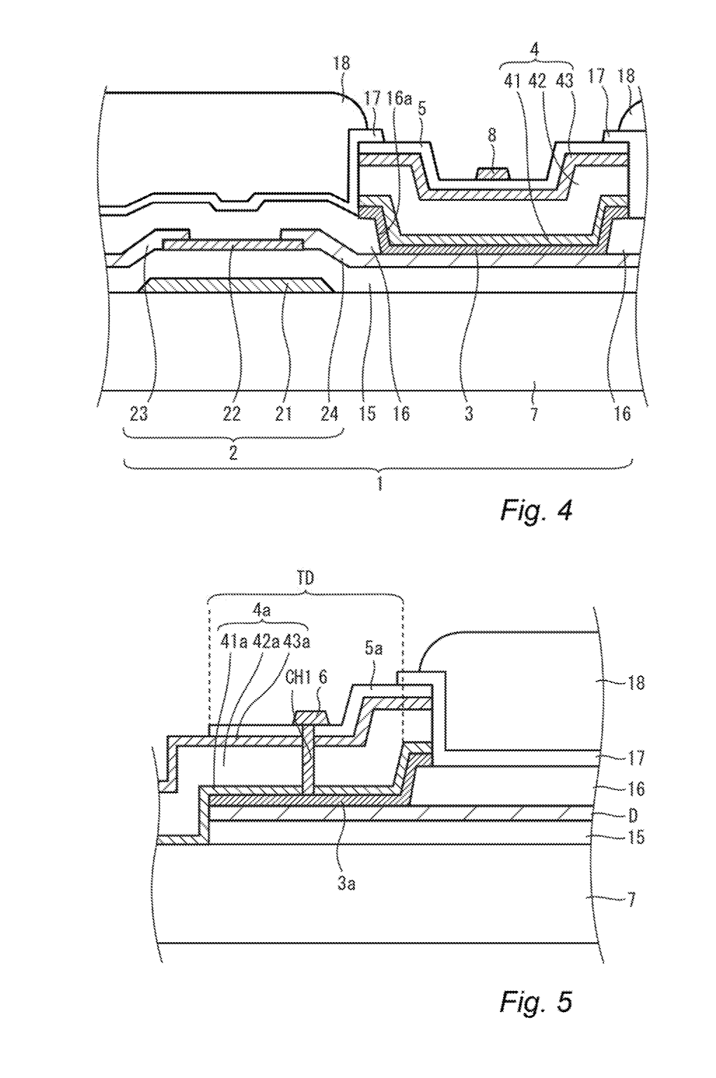

FIG. 3 is a view in the direction perpendicular to the substrate, depicting exemplary configurations of the sensor unit 1 and the terminal part TD. FIG. 4 is a sectional view taken along line IV-IV indicated in FIG. 3. FIG. 5 is a sectional view taken along line V-V indicated in FIG. 3. FIG. 3 depicts the configuration of the sensor unit 1 disposed correspondingly to the intersection point of an i-th data line Di and a j-th gate line Gj, and the configuration of the terminal part TD at an end of the data line Di.

The TFT 2 is positioned correspondingly to the intersection point of the data line Di and the gate line Gi. The TFT 2 includes a source electrode 23 connected to the data line Di, a gate electrode 21 connected to the gate line Gj, a drain electrode 24 connected to the lower electrode 3, and a semiconductor layer 22 disposed between the source electrode 23 and the drain electrode 24. The lower electrode 3 is provided in an area surrounded with the data line Di, a data line Di+1 adjacent thereto, the gate line Gj, and a gate line Gj+1 adjacent thereto. The photodiode 4 and the upper electrode 5 are provided to be overlapped with the lower electrode 3 in this area. FIG. 3 exemplifies a case where none of the lower electrode 3, the photodiode 4, and the upper electrode 5 are provided in an area overlapped with the TFT 2. The lower electrode 3, the photodiode 4, and the upper electrode 5 can alternatively be provided in the area overlapped with the TFT 2.

There is provided a bias line 8 positioned to be overlapped with the upper electrode 5. The bias line 8 is disposed to be connected with the upper electrode 5. The bias line 8 extends along the data line Di to outside the sensor area, and is connected also to the upper electrodes 5 of the other sensor units 1 aligned along the bias line. The bias line 8 is configured to apply reverse bias voltage to the photodiode.

As depicted in FIG. 4, the sensor unit 1 has a portion provided with the TFT 2. The portion is also provided, on a substrate 7, with the gate electrode 21 and a gate insulating film 15 covering the gate electrode 21. The semiconductor layer 22 is positioned to be overlapped with the gate electrode 21 via the gate insulating film 15 interposed therebetween. The semiconductor layer 22 is partially overlapped with the source electrode 23 and the drain electrode 24 provided integrally with the data line D. The source electrode 23 and the drain electrode 24 are disposed on the semiconductor layer 22, to face each other with a space provided therebetween.

The drain electrode 24 is connected with the photodiode 4 via the lower electrode 3. FIG. 4 exemplarily depicts the lower electrode 3 provided as a conductor layer connected to the drain electrode 24. The lower electrode 3 can alternatively be provided as a conductor layer integrated with the drain electrode 24.

The photodiode 4 is provided on the lower electrode 3 and is positioned to be overlapped with the lower electrode 3. The photodiode 4 according to this example is disposed on a layer provided with the source electrode 23 and the drain electrode 24 on the gate insulating film 15, in other words, a layer provided with the data line D and the TFT 2. The sensor area SA on the substrate 7 includes an area overlapped with the TFT 2, the data line D, and the gate line and provided with a first passivation layer 16. The first passivation layer 16 according to this example is disposed in an area not provided with the photodiode 4. The photodiode 4 is provided at an opening 16a of the first passivation layer 16 covering the TFT 2, the gate line G, and the data line D. FIG. 4 exemplarily depicts the photodiode 4 provided across an edge of the opening 16a of the first passivation layer 16. The photodiode 4 can alternatively be disposed within an area surrounded with the edge of the opening 16a.

The first passivation layer 16 is provided thereon with a second passivation layer 17. The second passivation layer 17 extends from above the TFT 2 to an end (edge) of the photodiode 4. The second passivation layer 17 covers the end of the photodiode 4. The second passivation layer 17 is provided thereon with a flattening film 18.

The photodiode 4 can include an n-type (n+) semiconductor layer 41, an i-type semiconductor layer 42, and a p-type (p+) semiconductor layer 43 stacked in the mentioned order. These semiconductor layers can be made of amorphous silicon or the like. The photodiode 4 is provided thereon with the upper electrode 5. The upper electrode 5 can be a transparent electrode made of ITO, IZO, ZnO, SnO, or the like. The upper electrode 5 is provided thereon with the bias line 8. The bias line 8 according to this example is patterned on a surface of the upper electrode 5. The bias line 8 can alternatively be patterned on an insulating film covering the upper electrode 5. In this case, the bias line 8 and the upper electrode 5 are connected to each other via a contact hole provided in the insulating film.

As depicted in FIG. 3, the data line Di led out of the sensor area is connected to the terminal part TD. The data line Di at the terminal part TD is provided thereon with a protective layer 4a overlapped with the data line. The data line Di is connected with a terminal conductor 6 via a contact hole provided in the protective layer 4a. More specifically, as depicted in FIG. 5, the data line Di led out of the sensor area is overlapped with a lower electrode layer 3a, the protective layer 4a, and an upper electrode layer 5a at the terminal part TD. The terminal conductor 6 is electrically connected to the data line Di via an opening penetrating the upper electrode layer 5a and the protective layer 4a to reach the lower electrode layer 3a, that is, a contact hole CH1.

The terminal conductor 6 is exposed to the upper surface of the terminal part TD. Specifically, the terminal conductor 6 is connected with the data line Di via the uppermost portion of the terminal part TD and the contact hole CH1 connected to the portion. The terminal conductor 6 is not necessarily exposed to the upper surface of the terminal part TD. For example, the terminal conductor 6 can be positioned to connect the upper electrode layer 5a provided on the upper surface of the terminal part TD and the lower electrode layer 3a connected to the data line Di.

The lower electrode layer 3a can be made of a material for the lower electrode 3 in the sensor unit 1. The protective layer 4a can be made of a material for the photodiode 4 in the sensor unit 1. The upper electrode layer 5a can also be made of a material for the upper electrode 5 in the sensor unit 1. The terminal part TD can be made similar in layer configuration to the sensor unit 1 including the lower electrode 3, the photodiode 4, and the upper electrode 5 stacked in the mentioned order. The protective layer 4a, which is connected to the data line Di led out to the terminal part TD and stacked thereon, can be made of the material for the photodiode 4 and can be made similar in layer configuration to the photodiode 4, which is connected to the drain electrode 24 of the TFT 2 in the sensor unit 1 and stacked thereon.

The lower electrode layer 3a, the protective layer 4a, and the upper electrode layer 5a at the terminal part TD can thus be formed in a step of stacking the layers in the sensor unit 1. For example, the protective layer 4a can be formed by patterning the photodiode 4. The data line Di can thus be protected at the terminal part TD without increase in the number of production steps.

FIGS. 4 and 5 exemplarily depict the protective layer 4a made of the material for the photodiode 4. Specifically, the protective layer 4a similarly includes an n-type semiconductor layer 41a, an i-type semiconductor layer 42a, and a p-type semiconductor layer 43a stacked in the mentioned order. The protective layer 4a can alternatively contain part of materials for the photodiode. For example, the protective layer 4a can be configured without including at least one of the n-type semiconductor layer 41a, the i-type semiconductor layer 42a, or the p-type semiconductor layer 43. Furthermore, the protective layer 4a can additionally include a layer that is not included in the photodiode 4.

The protective layer 4a at the terminal part TD can be made wider than the data line Di led out of the sensor area SA as exemplarily depicted in FIG. 3. FIG. 3 exemplarily depicts the data line Di that is wider at the terminal part TD than inside the sensor area SA. The data line Di at the terminal part TD has a rectangular shape in a planar view, and the protective layer 4a has a rectangular shape larger than the data line Di. The protective layer 4a is provided in an area larger than the data line Di at the terminal part TD to cover the end of the data line Di. In other words, the end of the data line Di at the terminal part TD is positioned inside an end of the protective layer of the protective layer 4a. The protective layer 4a is thus positioned to be overlapped with the end of the data line Di in the direction perpendicular to the substrate. The protective layer 4a thus protects the end of the data line Di at the terminal part TD.

FIG. 3 exemplarily depicts the upper electrode layer 5a and the lower electrode layer 3a at the terminal part TD, which are shaped identically with the data line Di in a planar view. The end of the data line Di at the terminal part TD is entirely overlapped with the protective layer 4a in this example. The end of the data line Di at the terminal part TD can alternatively be at least partially overlapped with the protective layer 4a.

The contact hole of the protective layer 4a at the terminal part TD has a circular sectional shape in a plane parallel to the substrate. Such a cornerless sectional shape (e.g. a circular or elliptical shape) of the contact hole achieves inhibition of electric discharge from the terminal conductor 6 provided in the contact hole.

FIGS. 3 to 5 exemplarily depict the terminal part TD of the data line D. The terminal part TG of the gate line G can be configured similarly to the terminal part TD of the data line D.

(Terminal Part According to Modification Examples)

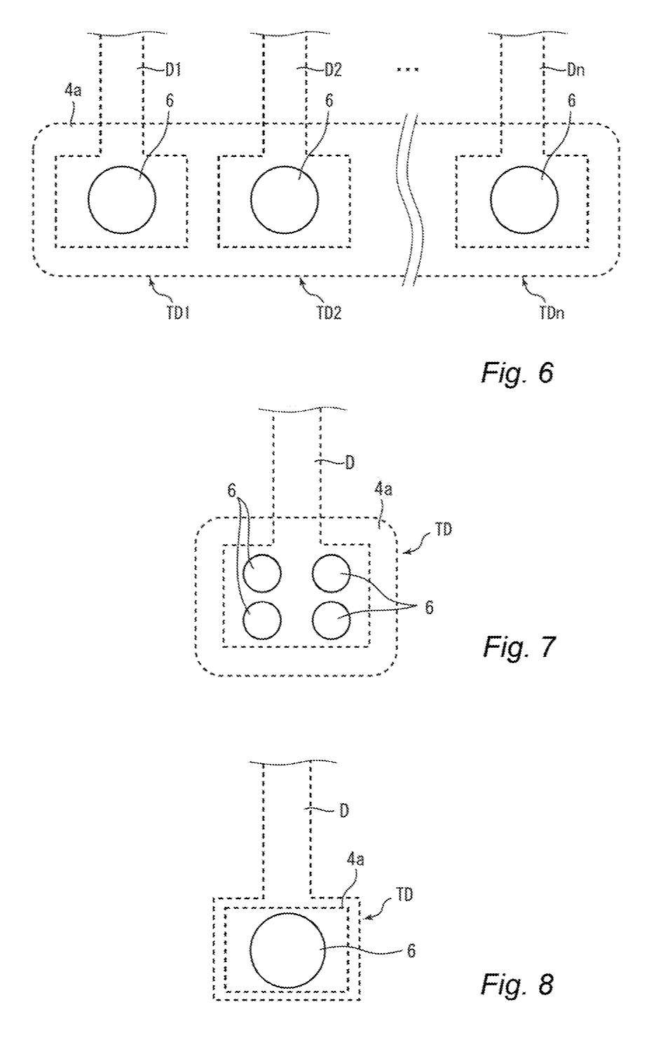

FIG. 6 is a view of terminal parts T according to a modification example. FIG. 6 exemplarily depicts the protective layer 4a that is integrally provided to be overlapped with a plurality of terminal parts TD. According to this example, the plurality of terminal parts TD1 to TDn connected to the plurality of data lines D1 to Dn, respectively, is aligned perpendicularly to the extending data lines D. The protective layer 4a extends in a single direction to cover the plurality of terminal parts TD1 to TDn aligned in the single direction. When viewed in the direction perpendicular to the substrate, the end (also called an outer rim or an edge) of the protective layer 4a surrounds the ends of the data lines D1 to Dn at the plurality of terminal parts TD1 to TDn.

The protective layer 4a, which covers the plurality of terminal parts TD and is provided integrally, is simplified in shape. The protective layer 4a can collectively protect the plurality of terminal parts TD that is disposed close to one another.

FIG. 7 is a view of a terminal part T according to another modification example. FIG. 7 exemplarily depicts the protective layer 4a provided with a plurality of openings serving as contact holes, at the single terminal part TD. The terminal conductors 6 are connected to the data line D provided therebelow via the contact holes. The layers above and below the protective layer 4a are conducted via the plurality of contact holes to be less likely to cause defective conduction. The plurality of contact holes can be provided as depicted in FIG. 7 at each of the terminal parts TD connected to the plurality of data lines D and each of the terminal parts TG connected to the plurality of gate lines G. The plurality of contact holes can alternatively be provided at some of the terminal parts T.

FIG. 8 is a view of a terminal part T according to still another modification example. FIG. 8 exemplarily depicts the protective layer 4a having the end positioned inside the end of the data line D at the terminal part TD when viewed in the direction perpendicular to the substrate. A different insulating layer such as the first passivation layer 16 or the second passivation layer 17 (see FIG. 5) can be disposed at a portion not overlapped with the protective layer 4a, of the data line D at the terminal part TD. FIG. 8 exemplarily depicts the protective layer 4a entirely overlapped on the data line D at the terminal part TD. The protective layer 4a can alternatively be disposed to be partially overlapped with the data line D.

The terminal parts T can be modified differently from the above modification examples. For example, these modification examples are applicable to the terminal parts TG of the gate lines G. The modification examples are also applicable to a terminal part connected to a line other than the gate lines G and the data lines D.

The protective layer 4a, the lower electrode layer 3a, the data line D, and the upper electrode layer 5a are not limited to have the rectangular shape when viewed in the direction perpendicular to the substrate. These elements can alternatively have a circular shape, an elliptical shape, or the like. The data line D, the lower electrode layer 3a, and the upper electrode layer 5a having a cornerless shape (e.g. a circular or elliptical shape) at the terminal part TD are less likely to cause electric discharge from the terminal part TD. The sectional shape in the plane parallel to the substrate, of the contact hole of the protective layer 4a is not limited to the circular shape but can have a rectangular shape or the like.

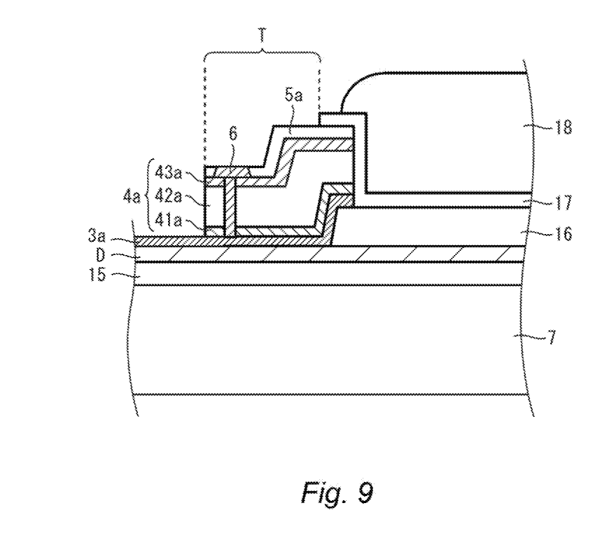

FIG. 9 is a view of a terminal part T according to still another modification example. FIG. 9 exemplarily depicts the terminal conductor 6 having an upper surface substantially flush with the upper surface of the upper electrode layer 5a. The protective layer 4a is provided thereon with the upper electrode layer 5a. The upper electrode layer 5a has a portion that is overlapped with the contact hole of the protective layer 4a in the direction perpendicular to the substrate and is provided with an opening. The terminal conductor 6 is filled in the contact hole of the protective layer 4a and the opening of the upper electrode layer 5a. The terminal conductor 6 is filled to have the upper surface substantially flush with the upper surface of the upper electrode layer 5a.

The upper electrode layer 5a disposed on the protective layer 4a is provided with the opening positionally corresponding to the contact hole of the protective layer 4a, and the terminal conductor 6 is provided in the contact hole and the opening, to achieve a configuration less likely to cause defective conduction.

The terminal conductor 6 can be provided in place of the upper electrode layer 5a at the terminal part T. Specifically, the protective layer 4a can be provided thereon with an electrode layer that is formed integrally with the terminal conductor 6 filling the contact hole of the protective layer 4a and expands on the entire upper surface of the terminal part T.

(Production Steps)

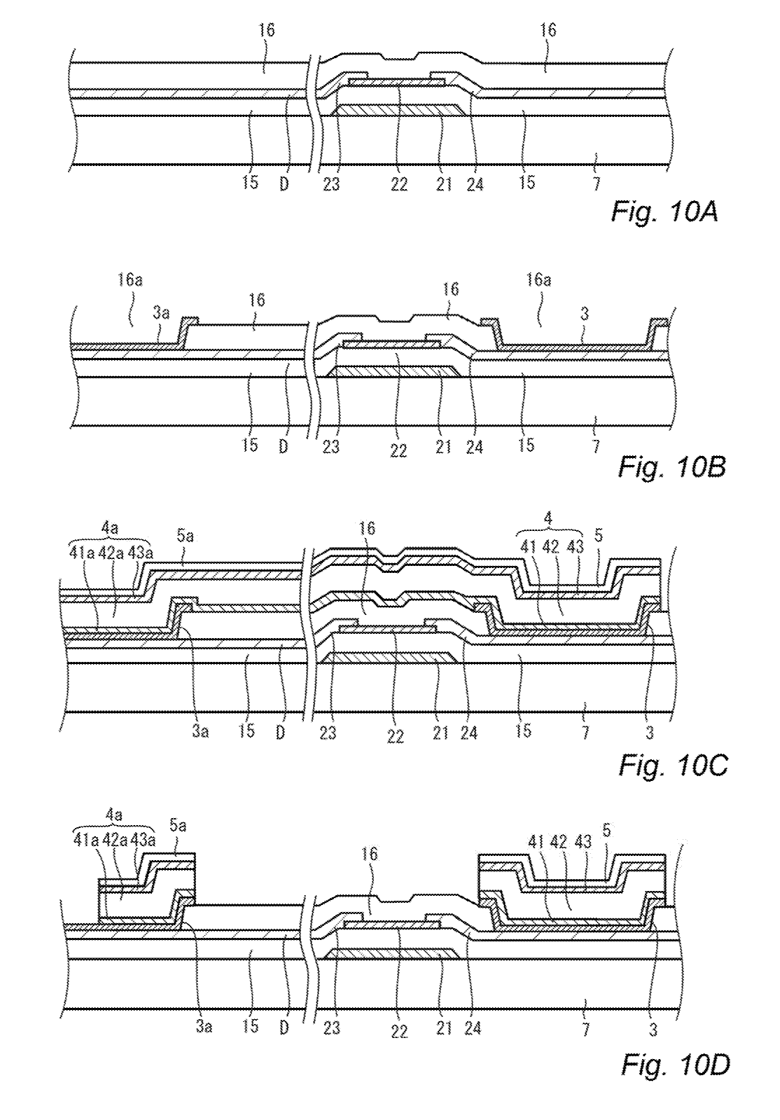

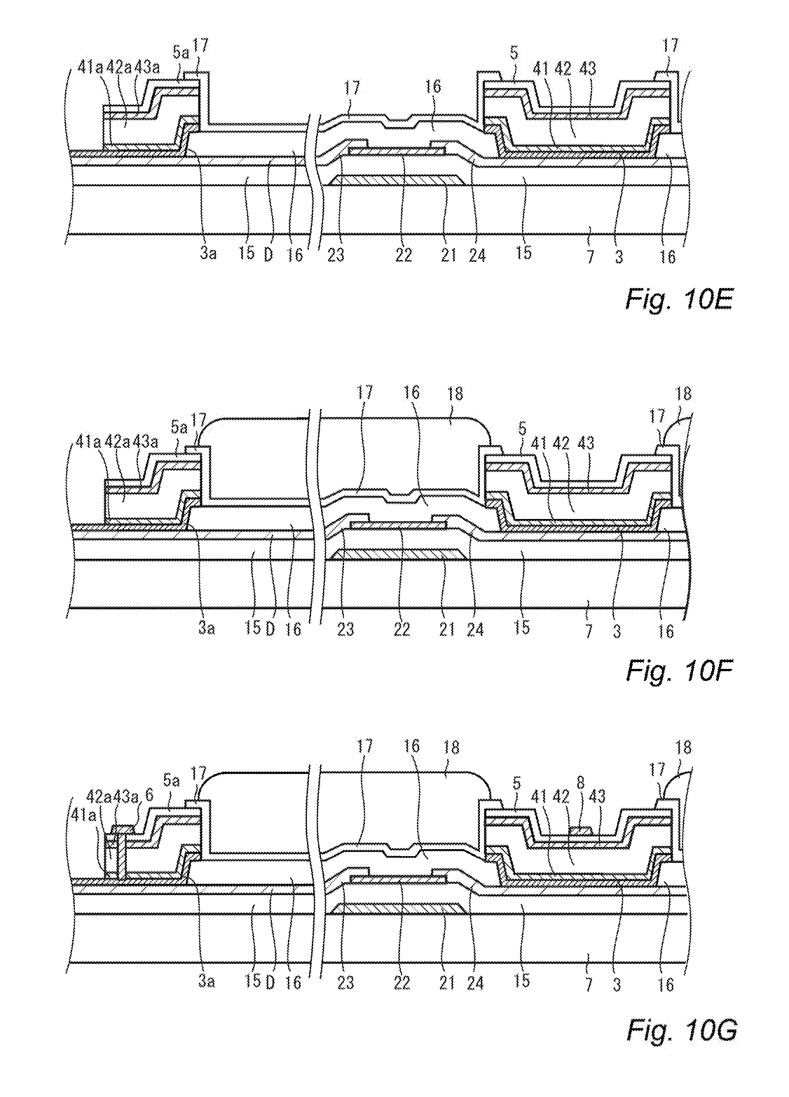

FIGS. 10A to 10G are views depicting exemplary steps of producing the photosensor substrate according to the present embodiment. FIGS. 10A to 10G each include a right side depicting a section of a portion provided with the terminal part T and a left side depicting a section of a portion provided with the sensor unit 1.

In order to reach the state depicted in FIG. 10A, the gate electrode 21 and the gate line G (not depicted in FIG. 10A) are initially formed on the substrate 7. The substrate 7 is made of an insulating material such as glass or resin. The gate electrode 21 and the gate line G are configured by a single film of either a metal film made of aluminum (Al), tungsten (W), molybdenum (Mo), tantalum (Ta), chromium (Cr), titanium (Ti), copper (Cu), or the like or a film containing an alloy thereof, or are configured by stacked films thereof. In order to form the gate electrode 21 and the gate line G, the substrate 7 is provided thereon with a film of a first conductor in accordance with the sputtering method, and the first conductor is provided thereon with a resist shaped correspondingly to the gate electrode 21 in accordance with the photolithography method. The first conductor is etched in the state where the resist is disposed thereon, to obtain the gate electrode 21 and the gate line G. The gate electrode 21 and the gate line G can typically be about 50 nm to 500 nm thick.

The gate insulating film 15 is formed in accordance with the PECVD method to cover the gate electrode 21 and the gate line G. Examples of the gate insulating film 15 include a silicon inorganic film containing nitrogen or oxygen/nitrogen (e.g. an SiNₓ film or an SiO₂ film) and stacked films of the SiO₂ film and the SiNₓ film. The gate insulating film 15 is typically 100 to 500 nm thick.

The gate insulating film 15 is provided thereon with a semiconductor film in accordance with the PECVD method. The semiconductor film is provided thereon with a resist in accordance with the photolithography method, and is etched to be patterned. The semiconductor layer 22 can thus be provided in the area corresponding to the TFT 2. Examples of the semiconductor layer 22 include an In—Ga—Zn—O oxide semiconductor film. The semiconductor layer 22 is optionally provided thereon with a contact layer. The semiconductor layer 22 can be 100 nm to 200 nm thick.

The gate insulating film 15 is provided thereon with a film of a second conductor configuring the data line D, the source electrode 23, and the drain electrode 24 in accordance with the sputtering method. The second conductor can configure a single film of either a metal film made of aluminum (AI), tungsten (W), molybdenum (Mo), tantalum (Ta), chromium (Cr), titanium (Ti), copper (Cu), or the like or a film containing an alloy thereof, or can configure stacked films thereof. The second conductor is patterned in accordance with the photolithography method to form the data line D, the source electrode 23, and the drain electrode 24. The second conductor is typically 50 to 500 nm thick.

The first passivation film 16 is formed in accordance with the PECVD method to cover the gate insulating film 15, the semiconductor layer 22, and the second conductor. This achieves the state depicted in FIG. 10A. The first passivation film 16 can typically be 100 to 500 nm thick.

In order to reach the state depicted in FIG. 10B, the first passivation layer 16 is provided with a resist and is etched. The opening 16a is thus provided in each of an area corresponding to the photodiode 4 in the sensor unit 1 and an area corresponding to the terminal part T. The first passivation layer 16 having the openings 16a is provided thereon with a third conductor configuring the lower electrode 3 and the lower electrode layer 3a. The third conductor is etched to be left in areas corresponding to the openings 16a of the first passivation layer 16. The openings 16a of the first passivation layer 16 are thus provided thereon with the lower electrode 3 and the lower electrode layer 3a.

In order to reach the state depicted in FIG. 10C, the first passivation layer 16, the lower electrode 3, and the lower electrode layer 3a are provided thereon with a semiconductor film having a PIN structure including a p+ layer, an i layer, and an n+ layer. The semiconductor film exemplifies a photoelectric conversion element layer and configures the photodiode 4 and the protective layer 4a. The semiconductor film is further provided thereon with a transparent electrode layer configuring the upper electrode 5 and the upper electrode layer 5a.

In a step of forming the semiconductor film, there are formed a P-doped amorphous silicon layer (41), an intrinsic amorphous silicon layer (42), and a B-doped amorphous silicon layer (43) in the mentioned order in accordance with the PECVD method or the like. The semiconductor film can be 1 to 1.5 μm thick.

The transparent electrode layer configuring the upper electrode 5 can be formed in accordance with the sputtering method using a target made of any one of indium tin oxide (ITO), indium zinc oxide (IZO), zinc oxide (ZnO), tin oxide (SnO), and the like.

In order to reach the state depicted in FIG. 10D, the semiconductor film and the transparent electrode layer are patterned in accordance with the photolithography method and by etching. The semiconductor film and the transparent electrode layer are thus left at portions overlapped with the lower electrode 3 in the sensor unit 1 and the lower electrode layer 3a at the terminal part T. The semiconductor film at the sensor unit 1 configures the photodiode 4 whereas the semiconductor film at the terminal part T configures the protective layer 4a. The semiconductor film as the photoelectric conversion element layer is provided at the openings 16a of the first passivation layer 16 in this step. Specifically, the semiconductor film is provided to cover exposed portions of the lower electrode 3 connected to the drain electrode 24 in the TFT 2 and the lower electrode layer 3a connected to the data line D (or the gate line G). This achieves formation of the photodiode 4 functioning as the photoelectric conversion element in the sensor unit 1, as well as formation of the protective layer 4a protecting a line such as the data line D or the gate line G at the terminal part T.

If the semiconductor film is entirely removed at the terminal part T in a step of patterning the semiconductor film, the lower electrode layer 3a at the terminal part T is more likely to be damaged by etching. In contrast, FIG. 10C exemplarily depicts the semiconductor film remaining on the lower electrode layer 3a at the terminal part T. Etching is thus less likely to damage the lower electrode layer 3a at the terminal part T in this state.

The semiconductor film and the transparent electrode layer are collectively patterned in this example. This simplifies the production step. The semiconductor film and the transparent electrode layer can alternatively be patterned separately from each other.

FIG. 10D exemplarily depicts the protective layer 4a covering an end of the first passivation layer 16 at the terminal part T. This configuration allows the data line D to be covered with no space provided between the first passivation layer 16 and the protective layer 4a. The protective layer 4a and the first passivation layer 16 can alternatively be disposed to have a space between their ends.

In order to reach the state depicted in FIG. 10E, an insulating film is formed to cover the first passivation layer 16, the protective layer 4a, the photodiode 4, the upper electrode 5, and the like, and is then patterned in accordance with the photolithography method and by etching. The patterning achieves formation of the second passivation layer 17 covering the first passivation layer 16, the end of the photodiode 4, and the end of the protective layer 4a. The lower electrode layer 3a at the terminal part T is covered with the protective layer 4a also in this state and is thus less likely to be damaged by etching upon formation of the second passivation layer 17.

In order to reach the state depicted in FIG. 10F, the flattening film 18 is formed on the second passivation layer 17. The flattening film 18 can be patterned typically in accordance with the photolithography method and by etching. The lower electrode layer 3a at the terminal part T is covered with the protective layer 4a in this case, and is thus less likely to be damaged by etching. The flattening film 18 can alternatively be made of photosensitive resin so as to be patterned through exposure and development.

In order to reach the state depicted in FIG. 10G, the protective layer 4a at the terminal part T is provided with a contact hole penetrating the protective layer 4a, and the third conductor is provided on each of the contact hole and the upper electrode 5 in the sensor unit 1. The contact hole is then filled with the third conductor. The third conductor at the terminal part T configures the terminal conductor 6 allowing conduction between the data line D below the protective layer 4a and the upper electrode layer 5a on the protective layer 4a. The third conductor at the sensor unit 1 configures the bias line 8 disposed on the upper electrode 5. Examples of a material for these third conductors include aluminum (AI), tungsten (W), molybdenum (Mo), tantalum (Ta), chromium (Cr), titanium (Ti), and copper (Cu).

The contact hole of the protective layer 4a can be formed in accordance with the photolithography method and by etching. The bias line 8 and the terminal conductor 6 are obtained by forming, after the contact hole is formed, a film of the third conductor in accordance with the sputtering method, and patterning the third conductor in accordance with the photolithography method and by etching. The lower electrode layer 3a is covered with the protective layer 4a in this state, and is thus less likely to be damaged by etching.

The above production steps cause less etching damage to the surface of the electrode at the terminal part T. This inhibits defective conduction due to a film residue or corrosion at the surface of the electrode at the terminal part T. Furthermore, the protective layer 4a protecting the surface of the electrode at the terminal part is formed by patterning the photodiode 4 and does not need any additional step for formation of the protective layer. The production method thus achieves inhibition of increase in the number of production steps as well as inhibition of surface deterioration at the terminal part of the line.

### Other Modification Examples

The invention of the present application is not limited to the embodiment described above. For example, the structure of the TFT 1 is not limited to the above example. According to the above example, the data line D, the source electrode 23, the drain electrode 24, and the lower electrode 3 are provided at an identical layer level, specifically, on the gate insulating film 15. At least one of the data line D, the source electrode 23, the drain electrode 24, or the lower electrode 3 can alternatively be provided at a different layer level, specifically, on an insulating layer further provided on the gate insulating film 15.

The photodiode 4 according to the above embodiment is configured by the semiconductor layers of the PIN structure. The photodiode 4 can alternatively have a PI structure or a Schottky structure. Furthermore, the semiconductor configuring the photodiode 4 and the protective layer 4a is not limited to amorphous silicon.

The above embodiment exemplifies the photosensor substrate applied to the X-ray image detection device. The photosensor substrate is not limitedly applied thereto. The photosensor substrate according to the present invention is also applicable to any other flat panel optical sensor for a γ-ray detection device and the like.

### REFERENCE NUMERALS

1 Sensor unit
2 TFT (exemplifying switching element)
3 Lower electrode
4 Photodiode (exemplifying photoelectric conversion element)
5 Upper electrode
6 Terminal conductor
7 Substrate
10 Photosensor substrate
D Data line
G Gate line
T, TG, and TD Terminal part

1. A photosensor substrate comprising a plurality of sensor units each including
a switching element, a lower electrode connected to the switching element, and a photoelectric conversion element disposed in contact with the lower electrode,
the photosensor substrate further comprising:
a line connected to the switching element in corresponding one of the sensor units and led out of a sensor area provided with the plurality of sensor units; and
a terminal part connected, outside the sensor area, to the line led out of the sensor area; wherein
the terminal part includes a protective layer overlapped with the line led out of the sensor area and containing a material for the photoelectric conversion element, and a terminal conductor connected to the line via at least one opening provided in the protective layer.

2. The photosensor substrate according to claim 1, wherein
the photoelectric conversion element is disposed above a layer having the line and at least in an area overlapped with the lower electrode, and
the protective layer containing the material for the photoelectric conversion element is disposed outside the sensor area, above the layer having the line, and at least in an area overlapped with the terminal part.

3. The photosensor substrate according to claim 1, wherein the line has an end provided at the terminal part and overlapped with the protective layer in a direction perpendicular to the photosensor substrate.

4. The photosensor substrate according to claim 1, wherein the at least one opening of the protective layer at the terminal part of at least one of the lines includes a plurality of openings.

5. The photosensor substrate according to claim 1, wherein
the lines include a plurality of gate lines extending in a first direction, and a data line provided on an insulating film to be different in layer level from the gate lines and extending in a second direction different from the first direction,
the switching element includes a gate electrode connected to corresponding one of the gate lines, a semiconductor layer positioned to face the gate electrode via the insulating film interposed therebetween, a source electrode disposed on the semiconductor layer and connected to the data line, and a drain electrode positioned to face the source electrode on the semiconductor layer and connected to the lower electrode,
the photoelectric conversion element is disposed on the lower electrode and is positioned to be overlapped with the lower electrode, and
the terminal part includes, outside the sensor area, the protective layer overlapped above the gate line or the data line, and the terminal conductor connected to the gate line or the data line via the opening of the protective layer.

6. The photosensor substrate according to claim 1, further comprising:
an upper electrode disposed on the photoelectric conversion element; and
an upper electrode layer disposed on the protective layer at the terminal part.

7. The photosensor substrate according to claim 1, wherein the photoelectric conversion element and the protective layer each include a p-type semiconductor layer, an n-type semiconductor layer, and an i-type semiconductor layer disposed between the p-type semiconductor layer and the n-type semiconductor layer.

8. An X-ray image detection device comprising:
the photosensor substrate according to claim 1; and
a scintillator layer positioned to be overlapped with the photoelectric conversion element of the photosensor substrate.

9. A method of producing a photosensor substrate, the method comprising:
forming, on a substrate, a line, a switching element connected to the line, and a lower electrode connected to the switching element:
forming a photoelectric conversion element layer covering at least the lower electrode and a portion to be provided with a terminal part of the line;
patterning the photoelectric conversion element layer to leave the photoelectric conversion element layer positioned to be overlapped with the lower electrode and the terminal part;
forming a through hole penetrating the photoelectric conversion element layer overlapped with the terminal part of the line; and
filling the through hole with a conductor.
